(19) United States
(12) Patent Application Publication
(10) Pub. No.: US 2023/0331084 A1
(43) Pub. Date: Oct. 19, 2023

(54) DISPLAY UNIT

(71) Applicant: VALEO COMFORT AND DRIVING ASSISTANCE, Créteil (FR)

(72) Inventors: Michael Irzyk, Creteil (FR); Stéphane Korczak, Creteil (FR); Regis Noll, Creteil (FR); Perig Danguillaume, Creteil (FR)

(73) Assignee: VALEO COMFORT AND DRIVING ASSISTANCE, Créteil (FR)

(21) Appl. No.: 18/026,900

(22) PCT Filed: Sep. 17, 2021
(86) PCT No.: PCT/EP2021/075720

§ 371 Date: Mar. 17, 2023

(30) Foreign Application Priority Data
Sep. 18, 2020 (FR) 2009496

(51) Int. Cl. B60K 35/00; H05K 5/00

(52) U.S. Cl. CPC B60K 35/00; H05K 5/0018; B60K 2370/1438; B60K 2370/1523; B60K 2370/343; B60K 2370/44

(57) ABSTRACT

A display unit (2) comprises a display (8), a plate (4) which is at least partially transparent and a structural part (6) comprising a rear portion (10) and a front portion (12) extending toward the plate (4) from the rear portion (10) while surrounding the display (8). The front portion (12) has a front face (30) extending at a constant distance from a rear face (32) of the plate (4) so as to form a bearing surface for the plate (4). The front portion (12) has at least one recess (28) arranged to form a passage between the rear portion (10) and the plate (4).

The present invention relates to the technical field of displaying, particularly in motor vehicles.

The present invention relates in particular to a display device comprising a display, an at least partially transparent sheet and a structural component.

Such display devices are notably used in motor vehicles for displaying information intended for the driver of the motor vehicle or for the passengers of this motor vehicle.

The sheet, made for example of glass, may cover the display device across the entire front face thereof, giving the display device an esthetically attractive appearance.

The structural component improves the mechanical integrity of the whole. This is advantageous particularly when the sheet has a curvature, in which case the structural component is shaped to keep the sheet at the desired curvature.

In that context, the invention proposes a display device comprising a display, an at least partially transparent sheet and a structural component comprising a rear part (or base) and a front part extending toward the sheet from the rear part and framing the display, the front part having a front face extending at a constant distance from a rear face of the sheet so as to form a bearing surface supporting the sheet, characterized in that the front part has at least one opening designed to form a passage between the rear part and the sheet.

Such an opening allows additional functionalities to be implemented at this point, such as a lead-through for an electric cable, or the creation of a fixing zone, without generating additional bulk.

For example, an electric cable connected to the display may be arranged in the passage so that it thus passes through the wall of the structural component.

In that case, the residual space in the opening may be filled with adhesive. In certain embodiments, adhesive may then be spread in places between the rear part and the sheet and/or, in the region of the electric cable, between the electric cable and the sheet.

According to another possibility, the opening may accommodate at least one element (for example a stud) for collaborating with a fixing tab belonging to an additional component (such as a retaining piece holding an element of the display or a decorative component attached to the structural component).

The front part may comprise a plurality of distinct openings (which is to say openings separated by regions of the front part), these openings (each) forming a passage between the rear part and the sheet. Thus, some of these openings may be used for leading cables through, as proposed hereinabove, while other openings may be used to contribute to fixing a component, as likewise proposed hereinabove.

In practice, the sheet may be curved. The structural component is particularly beneficial in such instances. Provision may then moreover be made for the front face to be inscribed in a cylinder, for example a cylinder of axis perpendicular to a normal to the display surface and, in the examples set out hereinafter, perpendicular to the longest direction of extension of the sheet. As a variant, the sheet may be flat.

According to one possible embodiment, with the passage being defined by a lateral wall orthogonal to the front face, the front part may have a connecting surface free of sharp corners (or rounded connecting surface) between the front face and this orthogonal lateral wall. This then avoids stresses that could have arisen in the sheet had there been a sharp corner between the front face and the lateral wall.

The sheet may be bonded to the front face. A coat of adhesive (or resin) is then interposed between the sheet and the front face.

Provision may also be made for an intermediate component to be interposed between the sheet and the front face.

This intermediate component may comprise a frame, onto which is/are bonded the sheet, and/or a part for fixing to the front part of the structural component.

The frame may possibly have a surface area greater than that of the front face, thereby offering greater design flexibility (particularly as regards the choice of the dimensions of the aforementioned opening).

The display may be at least in part bonded to the rear face of the sheet.

The display may comprise a light modulator mounted on the rear face of the sheet.

The aforementioned electric cable may then be connected to the light modulator. Such an electric cable is, for example, an electric cable powering and/or controlling the light modulator.

The display may also comprise an illumination unit. This illumination unit may be mounted on the aforementioned structural component. As a variant, the illumination unit may be mounted on a separate component, possibly fixed to the structural component.

In the example described hereinafter, the aforementioned retaining piece (of which a fixing tab collaborates with a collaborating element formed in the opening of the front part) is a retaining frame (for example a metal frame) holding the illumination unit.

According to another possible embodiment, the display may comprise a matrix of light-emitting elements. The display may in this case be mounted on the rear face of the sheet.

The aforementioned front part may have a rectangular overall shape framing the display. For example, the front part may be configured in such a way that the front face has lateral regions situated on each side of the display and at least one transverse band (extending from one lateral region to the other lateral region), or even two transverse bands (extending on each side of the display, each from one lateral region to the other lateral region).

The aforementioned opening may then form an interruption of one transverse band (of these transverse bands) and thus a break in the continuity of the front face in the region of this transverse band.

The sheet is for example made of glass. As a variant, the sheet could be made of plastic.

Finally, the display device may comprise a touch-sensitive matrix interposed between the display and the sheet. As a variant, such a touch-sensitive matrix could be integrated into the display (the display then being a “touch-sensitive” display).

Of course, the various features, variants and embodiments of the invention can be combined with one another in various combinations, as long as they are not mutually incompatible or mutually exclusive.

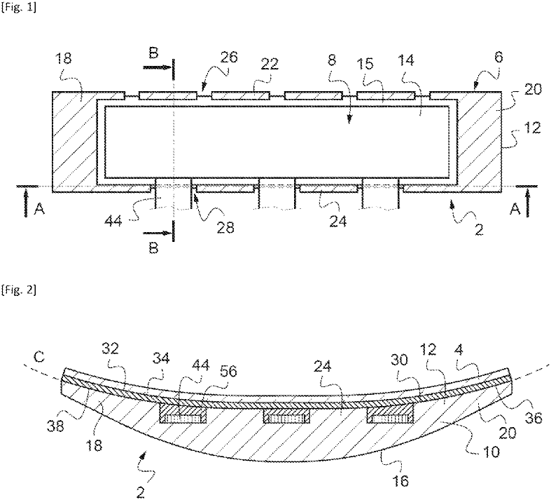

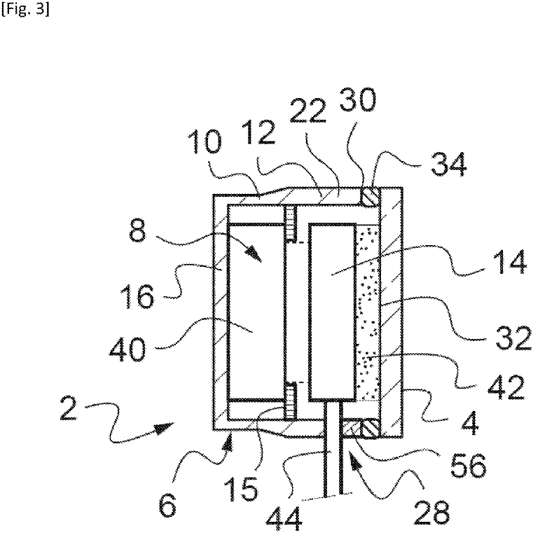

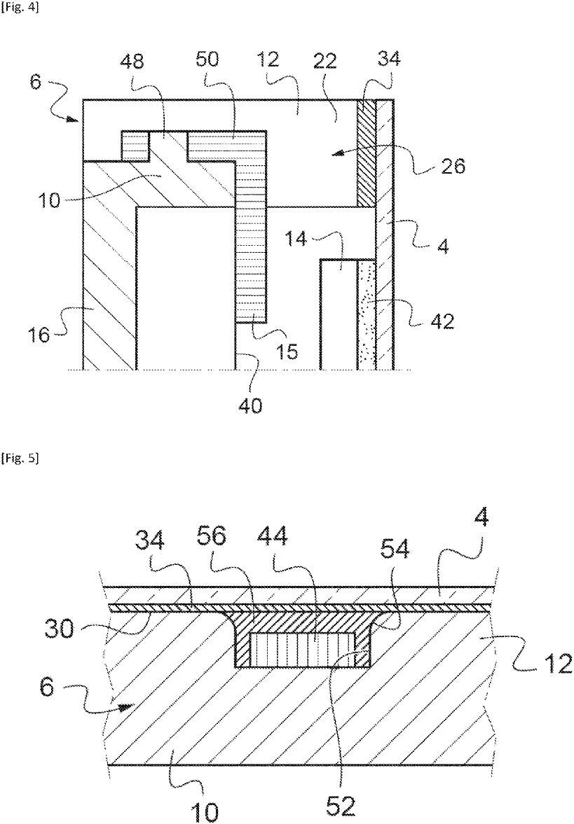

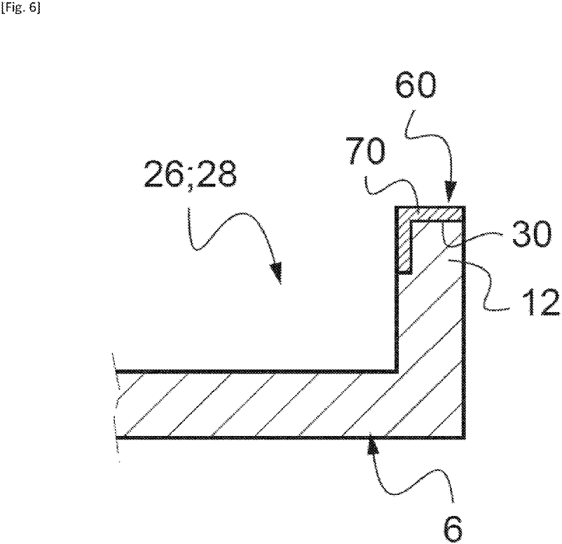

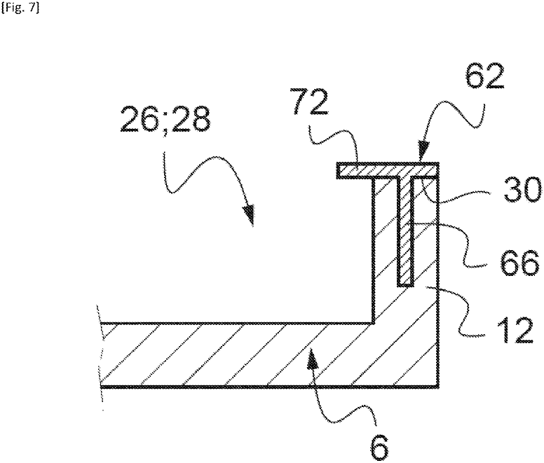

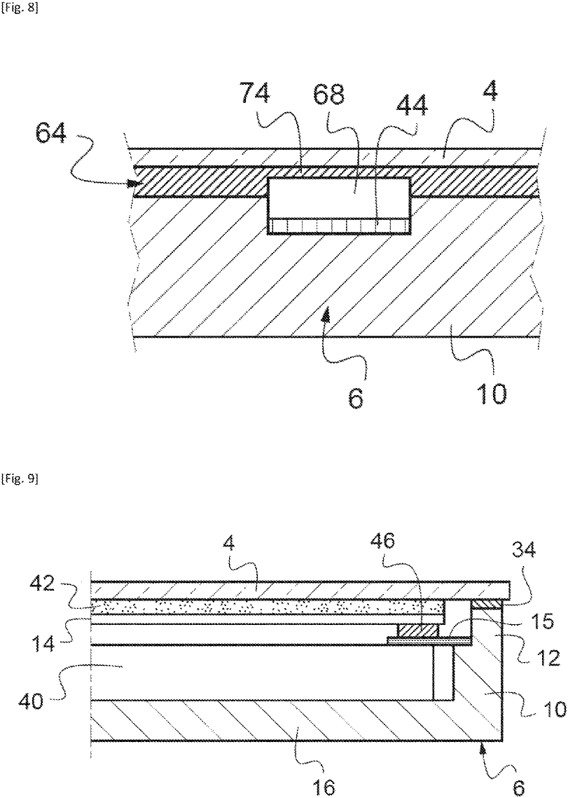

In addition, various other features of the invention will become apparent from the appended description, which is provided with reference to the drawings, which illustrate non-limiting embodiments of the invention and in which:

[FIG. 1] depicts a first view in section of a display device according to the invention;

[FIG. 2] depicts a second view in section (on the plane A-A visible in FIG. 1) of the display device of FIG. 1;

[FIG. 3] depicts a third view in section (on the plane B-B visible in FIG. 1) of the display device of FIG. 1;

[FIG. 4] illustrates a detailed view of the display device of FIG. 1;

[FIG. 5] depicts an embodiment variant of a structural component of such a display device;

[FIG. 6] depicts an embodiment variant in which the display device comprises an intermediate component;

[FIG. 7] depicts another embodiment variant in which the display device comprises an intermediate component;

[FIG. 8] is a view in section of such a display device comprising an intermediate component; and

[FIG. 9] depicts a view in section of the display device of FIG. 1.

FIGS. 1 to 4 and 9 depict a display device 2 comprising an at least partially transparent sheet 4 (or glazing), a structural component 6 and a display 8.

As is clearly visible in FIG. 2, the structural component 6 comprises a rear part (or base) 10 and a front part 12 extending toward the sheet 4 from the rear part 10.

The structural component 6 is, for example, made of metal (in this instance magnesium or a magnesium-based alloy, or alternatively of aluminum or an aluminum-based alloy). The structural component 6 may thus notably contribute toward dissipating the heat produced by the display 8.

As is clearly visible in FIG. 1, the front part 12 has a rectangular overall shape so that this front part 12 frames the display 8, in this instance a light modulator 14 of the display 8.

The rear part (or base) 10 here further comprises a back wall 16 so that the rear part 10 defines a housing to house the display 8.

However, as a variant, the back wall of the housing accommodating the display 8 could be produced using an additional component. In that case, the rear part 10 has no back wall and therefore has the overall shape of a frame.

The front part 12 of the structural component 6 comprises two lateral extensions 18, 20 which are situated on each side (in this instance horizontally, which is to say respectively on the left and on the right) of the display 8 (in this case of the light modulator 14).

The front part 12 of the structural component 6 also comprises two low walls 22, 24 which are situated on each side (in this instance vertically, which is to say respectively above and below) of the display 8 (in this case of the light modulator 14).

Each low wall 22, 24 extends between the two lateral extensions 18, 20, in this case from one lateral extension 18 to the other lateral extension 20.

Each low wall 22, 24 has at least one opening, in this case a plurality of openings 26, 28. In the embodiment described here, the front part 12 has a crenellated shape (in this case when viewed from above or when viewed from beneath) on account of the presence of these openings 26, 28. Thus, the front part 14 defines at least one crenelation (here a plurality of crenelations) in section in a plane (in this case horizontal) perpendicular to the mean plane of extension of the display 8. In other words, each low wall 22, 24 comprises a plurality of teeth which are separated (pairwise) by an opening 26, 28.

For each low wall 22, 24, the ratio between the length of low wall without an opening and the length of low wall with an opening is for example comprised between 20 and 0.5 and preferably between 4 and 10.

The front part 12 has a front face 30 (which is to say an external surface facing toward the sheet 4) that extends at a constant distance from a rear face 32 of the sheet 4 so as to form a bearing surface supporting the sheet 4.

In the embodiment described here, only a coat of adhesive 34 is interposed between the front face 30 of the front part 12 and the rear face 32 of the sheet 4, so that the sheet 4 can be mounted on this front face 30 using adhesive bonding.

The front face 30 thus comprises lateral regions 36, 38 formed by the respective external surfaces (facing toward the sheet 4) of the lateral extensions 18, 20 and two transverse bands formed by the respective external surfaces (facing toward the sheet 4) of the low walls 22, 24.

Each transverse band is, however, interrupted (in this case at several points) on account of the presence of the openings 26, 28. In other words, each transverse band exhibits (in this case at several points) a break in the continuity of the front face 30.

Each opening 26, 28 thus forms a passage between the rear part (or base) 10 and the sheet 4.

In the example described, as visible in FIG. 2, the sheet 4 covers the entirety of the front face of the display device 2.

The sheet 4 is for example made of glass. However, as a variant, the sheet 4 could be made of plastic, for example of poly(methyl methacrylate), or of polycarbonate or a combination of these two materials.

In the embodiment described here, the sheet 4 is curved (with a curvature in a plane perpendicular to the mean plane of extension of the display 8) and the front face 30 is inscribed inside a cylinder C. The axis of this cylinder C is in this case perpendicular to a normal to the mean plane of extension of the display 8. In the embodiment described, the axis of the cylinder C is vertical, which is to say in this case perpendicular to the mean direction (in this case horizontal) of greatest extension of the sheet 4.

The sheet 4 is for example formed by force (shaping step) then bonded to the front face 30.

The radius of curvature of the front face 30 (which is to say the radius of the cylinder C) is for example comprised between 1 m and 10 m. In other embodiments, notably when plastics are used in the manufacture of the sheet 4 and/or of the display 8, the radius of curvature of the front face 30 can be very small: this radius of curvature may be comprised between 3 cm and 50 cm.

In a variant, the sheet could be flat.

In the example described here, the display 8 comprises the light modulator 14 already mentioned and an illumination unit 40 that produces a beam of light toward the light modulator 14 (in order to back-light the light modulator 14). The display device 2 here further comprises a frame 15 (for example made of metal, produced here from sheet metal) forming a retaining piece holding the illumination unit 40, as visible in particular in FIGS. 3 and 9.

The light modulator 14 (for example a TFT LCD, which stands for “Thin-Film Transistor Liquid Crystal Display” tile) comprises a matrix of elements (the matrix is not depicted) the transmittance of which can be controlled in such a way that each element transmits (toward the sheet 4) a controllable proportion of the beam of light received from the illumination unit 40, making it possible to generate the image that is to be displayed.

In the aforementioned case of a TFT LCD tile for example, the light modulator 14 comprises at least one polarizer (not depicted). Specifically in that case, the light modulator 14 comprises a matrix of liquid crystal cells each of which controllably affect the polarization of the incident light (produced by the illumination unit 40). Thus, the presence of the aforementioned polarizer makes it possible to obtain at output a quantity of light that is dependent on the polarization imparted by the relevant cell and which is therefore adjustable by controlling this cell.

The illumination unit 40 is for example mounted on the structural component 6 (in the aforementioned housing). In the example described here, the illumination unit 40 is housed between the back wall 16 of the rear part (or base) 10 and the retaining piece (metal frame) 15, as is clearly visible in FIGS. 3 and 9. However, as a variant, the illumination unit 40 could be mounted on a part distinct from the structural component 6, this distinct part being able for example itself to be fixed to the structural component 6.

In the example described, the light modulator 14 is bonded to the sheet (by means of an optical adhesive 42), specifically in this case to the rear face 32 of the sheet 4.

As a variant, the display 8 could be produced by means of a matrix of light-emitting elements (for example using OLED (Organic Light Emitting Diode) technology). In that case, the display 8 in its entirety may be bonded to the sheet 4.

As visible in FIG. 9, a flexible seal 46 (such as a foam seal) is here interposed between the metal frame 15 and the light modulator 14 (for example around the entire periphery of the light modulator 14).

According to one possible embodiment, a matrix of detectors (for example capacitive detectors) may be interposed between the display 8 and the sheet 4 (in this case for example bonded between the light modulator 14 and the sheet 4) in order to form a touch-sensitive display device. As a variant, such a matrix of detectors could be integrated into the light modulator 14.

The display device 2 comprises at least one electric cable 44 (in this case a plurality of electric cables) for (electrically) connecting the display 8 to electric power supply and/or control circuits (which have not been depicted).

Each electric cable 44 may for example be a ribbon cable. Each electric cable 44 may for example carry power supply and/or control signals intended for the display 8 (in this case for the light modulator 14), and/or detection and/or measurement signals produced by the display 8 (or by the above-mentioned matrix of detectors).

In the example described here, each electric cable 44 connects the light modulator 14 to electric power supply and/or control circuits.

At least one of the electric cables 44 extends through the passage formed by an opening 28 between the rear part (or base) 10 and the sheet 4.

This electric cable 44 thus passes through the wall of the structural component 6 as close as possible to the display 8 (in this case specifically as close as possible to the light modulator 14 which, in the example described, is bonded to the rear face 32 of the sheet 4 as has already been mentioned). This then yields a simple and not excessively bulky arrangement of the various elements of the system.

As visible in FIG. 2, provision may further be made for the residual space of the opening 28 (when the electric cable 44 is present, which is to say mainly the space between the electric cable 44 and the sheet 4) to be filled with the adhesive 34 applied between the front face 30 of the front part 12 and the rear face 32 of the sheet 4, and also possibly with another adhesive 56 applied in this case between the electric cable 44 and the adhesive 34, as depicted for example in FIG. 2. This then fixes the electric cables 44 in place and improves the mechanical integrity of the whole. (For the sake of clarity, FIG. 1 has been drawn without depicting the adhesive present in the openings 28.)

The structural component 6 moreover comprises fixing zones for fixing a component (such as in this case the aforementioned retaining piece 15 or, as a variant, another component such as a cover mounted, for example, to the rear of the structural component 6) respectively in the region of some of the openings 26, respectively in the region of the openings 26 formed in the low wall 22 situated above the display 8 in the example depicted in the figures.

Such fixing zones may also be arranged in the low wall 24 (situated below the display 8 in FIG. 1), but, for the sake of simplicity, these have not been depicted in the drawings.

Such a fixing zone is depicted in FIG. 4.

For at least one fixing zone (in this case for each fixing zone), the structural component 6 bears, in this case on the rear part 10, a stud 48 formed on part of the structural component 6 (in this case on part of the rear part 10) bordering the opening 26, and designed to collaborate (in this case by snap-fastening) with a fixing tab 50 secured to the component being fixed, which is to say in this case secured to the retaining piece (or metal frame) 15. In the example described here, the fixing tab 50 is formed of a piece with the retaining piece (or metal frame) 15.

As visible in FIG. 4, the fixing tab 50 extends in part through the passage formed (by the opening 26) between the sheet 4 and the rear part 10, and can thus reach (from the retaining piece 15 situated in the housing formed by the structural component 6 and accommodating the display 8) the stud 48 formed on the outside of the structural component 6.

FIG. 5 depicts an embodiment variant for the front part 12 of the structural component 6.

As visible in this FIG. 5, the passage formed by an opening 26, 28 (or this opening itself) is notably defined by a lateral wall 52 orthogonal to the front face 30.

According to the present variant, the front part 12 has a connecting surface 54 free of sharp corners between the front face 30 and this lateral wall 52.

This connecting surface has, for example, a radius of curvature of between 0.1 mm and 20 mm.

Such a rounded connecting surface 54 limits the stresses generated within the sheet 4.

As visible in FIG. 5, the two lateral walls orthogonal to the front face 30 and defining the opening 26, 28 concerned may each be connected to the front face 30 by such a connecting surface free of sharp corners (or rounded connecting surface).

FIGS. 6 to 8 depict embodiment variants in which an intermediate component 60, 62, 64 is interposed between the sheet 4 and the front face 30 of the front part 12 of the structural component 6.

The intermediate component 60, 62, 64 notably comprises a frame 70, 72, 74 interposed between the front face 30 and the sheet 4. The sheet 4 may thus be fixed (for example bonded) to this frame 70, 72, 74.

The intermediate component 60, 62, 64 may be made of metal or of plastic, offering additional design flexibility.

As visible in FIG. 7, the frame 72 may have a surface area greater than that of the front face 30 (for example on account of the fact that the frame 72 projects beyond the front face 30 at the front of the opening 26, 28 concerned), making it possible to provide better retention of the sheet 4. Furthermore, this greater surface area is obtained while at the same time maintaining flexibility in the choice of the size of the opening 26, 28, for example so as to allow electric cables 44 to be led through, as explained previously.

According to a first embodiment (depicted in FIG. 6), the intermediate component 60 has a shape (in this case an L-shaped cross section) that complements part of the structural component 6 (in this case part of the front part 12). The intermediate component 60 is then inserted into and/or bonded against the structural component 6.

According to a second embodiment (depicted in FIG. 7), the intermediate component 62 comprises a part (for example a shank 66) extending toward the rear (i.e. toward the structural component 6) and allowing the intermediate component to be fixed on the front part 12 of the structural component 6 (for example by forcible insertion, possibly into an aperture made in the structural component 6, or by adhesive bonding). The intermediate component 62 then has a T-shaped cross section.

According to one possible embodiment depicted in FIG. 8, the residual space in the opening 28 concerned is filled with an adhesive or with a resin 68 in order to stiffen the whole. This residual space may be formed between the intermediate component 64 (specifically the frame 74 of this intermediate component 64) and the structural component 6. According to another possibility, when an electric cable 44 is housed in the opening 28 concerned, as depicted in FIG. 8, this residual space may be formed between the intermediate component 64 (specifically the frame 74 of this intermediate component 64) and the electric cable 44.

1. A display device comprising:
a display;
an at least partially transparent sheet; and
a structural component comprising a rear part and a front part extending toward the sheet from the rear part and framing the display, the front part having a front face extending at a constant distance from a rear face of the sheet so as to form a bearing surface supporting the sheet,
wherein the front part has at least one opening designed to form a passage between the rear part and the sheet.

2. The display device as claimed in claim 1, wherein an electric cable connected to the display is arranged in the passage.

3. The display device as claimed in claim 2, wherein the residual space in the opening is filled with adhesive.

4. The display device as claimed in claim 1, wherein the opening accommodates at least one element for collaborating with a fixing tab belonging to an additional component.

5. The display device as claimed in claim 4, wherein the additional component is a retaining component holding an element of the display.

6. The display device as claimed in claim 1, wherein the sheet is curved and wherein said front face is inscribed in a cylinder.

7. The display device as claimed in claim 1, wherein the passage is defined by a lateral wall orthogonal to the front face and the front part has a connecting surface with no sharp corners between the front face and said orthogonal lateral wall.

8. The display device as claimed in claim 1, wherein the sheet is bonded to said front face.

9. The display device as claimed in claim 1, wherein an intermediate component is interposed between the sheet and the front face.

10. The display device as claimed in claim 9, wherein the intermediate component comprises a frame onto which the sheet is bonded.

11. The display device as claimed in claim 9, wherein the intermediate component comprises a part for fixing to the front part of the structural component.

12. The display device as claimed in claim 1, wherein the front part has a plurality of distinct openings each forming a passage between the rear part and the sheet.

13. The display device as claimed in claim 1, wherein the display is at least partially bonded to said front face.

14. The display device as claimed in claim 2, wherein the display comprises a light modulator mounted on said rear face.

15. The display device as claimed in claim 14, wherein the electric cableis connected to the light modulator.

16. The display device as claimed in claim 1, wherein the display comprises an illumination unit mounted on the structural component.

17. The display device as claimed in claim 1, wherein said front part is of rectangular overall shape framing the display.

18. The display device as claimed in claim 1, wherein the front part is configured such that the front face has lateral regions situated on each side of the display, and at least one transverse band.

19. The display device as claimed in claim 18, wherein said opening forms an interruption of the transverse band.

20. The display device as claimed in claim 1, wherein the sheet is made of glass.

21. The display device as claimed in claim 1, comprising a touch-sensitive matrix interposed between the display and the sheet.
